(19) United States
(12) Patent Application Publication
(10) Pub. No.: US 2009/0073737 A1
(43) Pub. Date: Mar. 19, 2009

(54) Integrated Circuits; Methods for Manufacturing an Integrating Circuit; Memory Modules

(76) Inventors: Ulrich Klostermann, Munich (DE); Rainer Leuschner, Regensburg (DE)

Correspondence Address: SLATER & MATSIL, L.L.P., 17950 PRESTON ROAD, SUITE 1000, DALLAS, TX, 75252, US

(21) Appl. No.: 11/856,659

(22) Filed: Sep. 17, 2007

(51) Int. Cl. G11C 7/02; G11C 11/02; H01L 21/00

(52) U.S. Cl. 365/53; 365/158; 438/3; 257/E21.001

(57) ABSTRACT

Embodiments of the invention relate generally to integrated circuits, to methods for manufacturing an integrating circuit, and to memory modules. In an embodiment of the invention, an integrated circuit is provided having a memory cell. The memory cell may include a first magnetic layer structure, a tunnel barrier layer structure disposed above the first magnetic layer structure, a second magnetic layer structure disposed above the tunnel barrier layer structure, and at least one sacrificial material layer to suppress electrochemical corrosion of the first magnetic layer structure or the second magnetic layer structure.

### TECHNICAL FIELD

Embodiments of the invention relate generally to integrated circuits, to methods for manufacturing an integrating circuit, and to memory modules.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a cross sectional view of a conventional magnetic element;

FIG. 2 shows a first embodiment of a magnetic element in accordance with the invention using a sacrificial anode layer;

FIG. 3 shows shows a second embodiment of a magnetic element in accordance with the invention using a sacrificial anode layer;

FIG. 4 shows a third embodiment of a magnetic element in accordance with the invention using a sacrificial anode;

FIG. 5 shows a fourth embodiment of a magnetic element in accordance with the invention using a sacrificial anode;

FIG. 6 shows a flow diagram of a method for manufacturing an integrated circuit according to one embodiment of the invention;

FIG. 7 shows a flow diagram of a method for manufacturing an integrated circuit according to another embodiment of the invention; and

FIGS. 8A and 8B show a memory module (FIG. 8A) and a stackable memory module (FIG. 8B) in accordance with an embodiment of the invention.

### DETAILED DESCRIPTION OF ILLUSTRATIVE EMBODIMENTS

Semiconductors are widely used for integrated circuits for electronic applications, including radios, televisions, cell phones, and personal computing devices, as examples. One type of semiconductor device having one more integrated circuit is a semiconductor storage device, such as a dynamic random access memory (DRAM) device or a flash memory device, which use electrical charges to store information.

Spin electronics combines semiconductor technology and magnetics, and is a more recent development in memory devices. In spin electronics, the spin of an electron, rather than electrical charges, is used to indicate the presence of a logical “1” or a logical “0”. One such spin electronic device is a magnetoresistive random access memory (MRAM) device.

MRAM technology is a non-volatile random access memory technology that could potentially replace the dynamic random access memory (DRAM) as the standard memory for computing devices. For example, a personal computer (PC) utilizing MRAM devices would not have a long “boot-up” time as with conventional PCs that utilize DRAM devices. Furthermore, an MRAM device does not need to be powered up and has the capability of “remembering” the stored data in a non-volatile manner. Therefore, it is expected that MRAM devices might replace flash memory, DRAM and static random access memory devices (SRAM) devices in electronic applications where a memory device is needed.

An MRAM cell (e.g. a tunneling magnetoresistive or TMR-device) includes a structure having ferromagnetic layers respectively exhibiting a resultant magnetic moment vector separated by a non-magnetic layer (or tunneling barrier) and arranged into a magnetic tunnel junction (MTJ). In contrast to the conventional non-volatile DRAM memory technology, digital information is not stored using electrical charges, but rather is represented in the MRAM cell as directions of magnetic moment vectors (magnetization directions) in the ferromagnetic layers. More specifically, the magnetic moment vector of one ferromagnetic layer structure (including one or more ferromagnetic layers) may be magnetically fixed (or pinned), while the magnetic moment vector of the other ferromagnetic layer structure (including one or more ferromagnetic layers) is free to be switched between the two preferred directions in the magnetization easy axis, which typically is arranged to be aligned with the fixed magnetization of the reference magnetic layer structure. Hence, a memory state of an MRAM cell is maintained by the direction of the magnetization of the free magnetic layer structure with respect to the direction of the magnetization of the reference magnetic layer structure.

Depending on the at least two different magnetic states of the free magnetic layer structure, the MRAM cell may exhibit two different resistance values in response to a voltage applied across the magnetic tunneling junction barrier structure. The orientations of the magnetic moment vector of the free magnetic layer structure are also known as “parallel” state and “anti-parallel” state, respectively, wherein a parallel state may refer to the same magnetic alignment of the free magnetic layer structure and the reference magnetic layer structure, while an anti-parallel state may refer to opposing magnetic alignments of the free magnetic layer structure and the reference magnetic layer structure. Accordingly, a memory state of a magnetic memory cell is not maintained using electrical charges as in DRAMs, but rather using the direction of the magnetic moment vector of the free magnetic layer structure with respect to the direction of the magnetic moment vector of the reference magnetic layer structure.

The layers of the stack including the mentioned layer structures are typically deposited in overlying blanket films, layer by layer, and then patterned. Since MRAM devices operate differently than conventional memory devices, they introduce design and manufacturing challenges with respect to the feature size. The magnetic material layer structures used in MRAM devices require different etch chemistries and processes than conventional materials used in semiconductor processing, making them difficult to integrate into MRAM manufacturing processing schemes.

The manufacturing of an MRAM device may include plasma etching processes in which one or more layers of an MRAM film stack are removed, either partially or entirely. For example, the MRAM tunnel junction (TJ) memory cell patterning is carried out by chemical assisted hard mask opening with reactive ion etching (RIE). Additionally, the free magnetic layer structure and also the reference system (e.g. the reference magnetic layer structure) may be patterned by e.g. sputter etch or chemical assisted etch. Both chemically assisted RIE processes and some post etch cleans such as DI rinse can electrochemically attack the magnetic stack including the above mentioned layer structures. The MRAM film stack may include materials that are sensitive to corrosion and may be easily oxidized, eroded, or damaged during etching.

The corrosion of the magnetic stack materials can either attack the magnetic properties of the free layer system (e.g. the free magnetic layer structure) or the reference system (e.g. the reference magnetic layer structure) or both. The DI rinse after the stack etch may damage the correct offset balancing of the reference system as part of the reference system corrode during the DI rinse.

However, this damage depends not only on the electrochemical properties of the damaged magnetic layers but also on the electrochemical potentials of the neighboring layers being in physical contact with the functional magnetic layers.

In an embodiment of the invention, an improved layer system is provided for a gentle etching of magnetic materials for fabrication of a memory cell, e.g. of a magnetoresistive random access memory (MRAM) device.

The term “ferromagnetic” used herein includes, but is not limited to, ferromagnets and ferrimagnets.

The embodiments of the invention are described in the context of single elements. However, one of ordinary skill in the art will readily recognize that the invention is consistent with the use of magnetic memories having multiple elements (hundreds, thousands, millions or even billions), which may be coupled with each other e.g. using connection lines such as e.g. bit lines and word lines.

A conventional MRAM device is illustrated in FIG. 1. The conventional magnetic element 10 includes a antiferromagnetic seed layer structure 100, a pinned reference magnetic layer structure 110, a non-magnetic spacer layer structure 120 and a free magnetic layer structure 130. Formed on or above the free magnetic layer structure 130 is a cap layer structure 140. A mask layer structure, e.g. a hard mask structure, is formed on or above the cap layer structure 140.

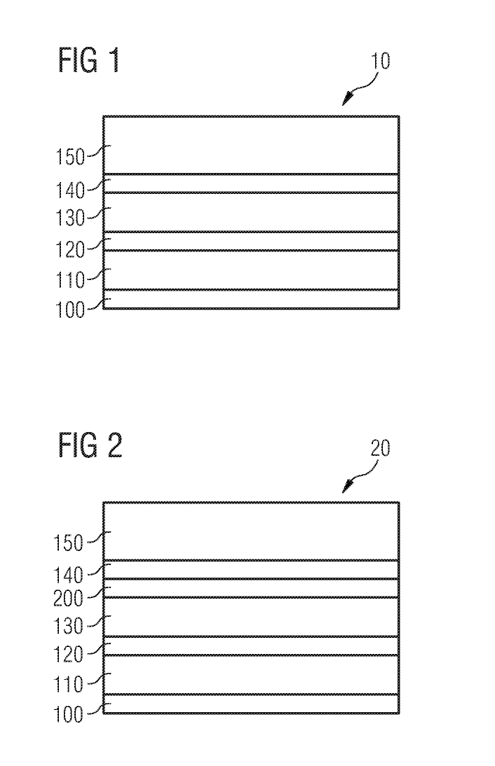

To more particularly illustrate the methods and systems in accordance with embodiments of the invention, reference is made to FIGS. 2 to 7. The materials that are used in accordance with various embodiments of the invention will be described in more detail below.

As shown in FIG. 2, in an embodiment of the invention, the magnetic element 20 includes a seed layer structure 100, a reference magnetic layer structure 110, a spacer layer structure 120 and a free magnetic layer structure 130. On or above the free magnetic layer structure 130, there is provided a first sacrifical anode layer 200. On or above the sacrificial anode layer 200 a cap layer structure 140 is deposited, on which a mask layer structure 150, e.g. a hard mask 150 is provided.

In an embodiment of the invention, the seed layer structure 100 includes one or more seed layers. Furthermore, the seed layer structure 100 may include WN, TaN, Ta, CuN, Cu, Ru, NiFeCr and combinations thereof to prevent corrosion of the first ferromagnetic layer structure during the etching of the magnetic stack.

In an embodiment of the invention, the reference magnetic layer structure 110 may be a permanent magnet also often referred to as hard magnetic layer or reference magnetic layer or first magnetic layer set to a particular magnetic polarity. The reference magnetic layer structure is ferromagnetic. For example, the reference magnetic layer structure might include at least one of the following materials: Co, Ni, Fe, combinations thereof or their alloys; PtMn, IrMn, Ru, NiFe, CoFe, CoFeY, where Y is between 5 and 50 atomic percent of at least one of B, Ta, Hf, Zr, Pt, Tb, and Ru. In one embodiment of the invention, the reference magnetic layer structure includes a plurality of ferromagnetic layers which might include at least two ferromagnetic layers, e.g. CoFe or CoFeB, which may be separated by a layer made of a material which may be selected from a group of materials consisting of at least one of Ru, Os, Ir, Rh, Re, Mn, Cr and V. In an embodiment of the invention, the reference magnetic layer structure includes a pinning structure, wherein the pinning structure may include PtMn or IrMn, for example.

The spacer layer 120 may also be referred to as tunnel barrier or T-barrier. These terms are used interchangeably in the context of this description. The spacer layer 120 may be non-magnetic and may be an insulating barrier layer, for example composed of a material selected from the group of materials consisting of: Cu, Al, Au, Al₂O₃, MgO, Si₃N₄, NiO, HfO₂, TiO₂, NbO and SiO₂.

In an embodiment of the invention, one of the layers is a magnet which field will change to match that of an external field. Such a layer is referred to as the free magnetic layer structure 130 or second magnetic layer structure. The free magnetic layer strucutre may be ferromagnetic and may include at least one of the elements Co, Fe or Ni and alloys thereof. In one embodiment of the invention, the free magnetic layer structure may be a single free magnetic layer, for example containing a single material or an alloy of multiple materials. In one embodiment, the free magnetic layer structure may include Fe, Co, Ni and combinations or alloys thereof, CoFeY, wherein Y is between five and fifty atomic percent of at least one of B, Ta, Hf, and Zr. In an exemplary embodiment, the layer thickness of the free magnetic layer structure is in the range of 10 Å to 60 Å. The ferromagnetic free layer strucure may have a magnetization direction that changes its orientation relative to that of the ferromagnetic reference layer structure over a range of applied magnetic fields, e.g. the applied magnetic fields used to store data.

In an embodiment of the invention, one or more sacrificial anode layers are deposited between the layers of the layer stack of the resistive semiconductor memory device. The sacrificial anode layer may be capable of protecting the magnetic stack, i.e. the reference magnetic layer structure and the free magnetic layer structure as well as the tunnel barrier of a resistive semiconductor memory device. During an etching process, the sacrificial anode layer may be attacked first due to its properties and chemical composition. Due to this, the memory device may be conserved and the electrochemical properties and potentials of the device as such may be preserved. In an embodiment of the invention, the material of the sacrificial anode layer should be a material which will react with the substances used in the etching process much easier than the material of the other layers of the memory device. For example, the sacrificial anode layer can be selected from the group consisting of Al, Mg, Zn, Ti, CoFeB, wherein in an embodiment of the invention, B may have a percentage of greater than about 40% in the CoFeB, and combinations thereof.

In an embodiment of the invention, one or more sacrificial anode layers may be used in the design of the resistive semiconductor memory device. The number of the sacrificial anode layers and the respective positions of the layers in the memory stack may depend on the properties of the layers which should be protected in an etching process. The sacrificial anode layer(s) may be disposed between at least two of the layers other than between the first magnetic layer structure and the tunnel barrier structure or between the tunnel barrier structure and the second magnetic layer structure. Furthermore, in one embodiment if the invention, the sacrificial anode layer(s) may be provided within one of the following layer structures, for example the seed layer structure, the cap layer structure or the mask layer structure. In this particular case, the sacrificial anode layer(s) is/are present in-between the splitted parts of the respective layer structure.

In an embodiment of the invention, the cap layer structure 140 includes a thin layer of protective material adapted to prevent diffusion of the metal. In an embodiment of the invention, the cap layer structure 140 includes an electrically conductive material such as for example tantalum nitride (TaN) or titanium nitride (TiN), CuN, Ru, Al and combinations thereof protecting the magnetic stack materials from oxidation.

In an embodiment of the invention, a mask layer structure 150 such as e.g. a hard mask structure is a material that is not etch-selective with respect to the cap layer structure 140. The mask layer structure 150 may for example include or consist of TaN, TiN, Ti, W, WN, Ta, SiO₂ and combinations thereof.

Although the embodiment shown in FIG. 2 has only one single free magnetic layer, alternatively, the resistive semiconductor memory device may include a plurality of free magnetic layers, each being separated by a non-magnetic tunnel barrier. In the case that the memory device includes a plurality of free magnetic layers, the magnetic coupling between the free magnetic layers may be predominantly magnetostatic. In addition, the plurality of free magnetic layers each have a magnetization direction that can be changed by the applied magnetic fields.

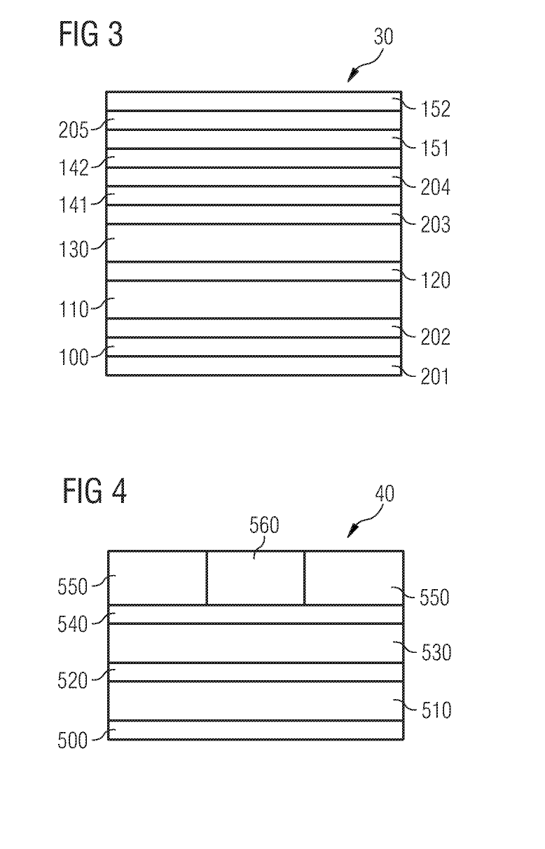

In a further embodiment of the invention the resistive semiconductor memory device 30 may have the following design as illustrated in FIG. 3.

The bottom layer may be a first sacrificial anode layer 201. On top of the first sacrificial anode layer 201 there may be a seed layer structure 100, followed by a second sacrificial anode layer 202. Furthermore, the reference magnetic layer structure 110 is provided as well as the spacer layer structure 120 and the free magnetic layer structure 130. A third sacrificial anode layer 203 may be deposited on or above the free magnetic layer structure 130. In an embodiment of the invention, a first cap layer 141 and a second cap layer 142, divided by a fourth sacrificial anode layer 204, may be provided. The topmost layers of the stack on top of the second cap layer 142 may be a first hard mask layer 151, a fifth sacrificial anode layer 205 and a second hard mask layer 152.

The above described embodiment discloses several sacrificial anode layers in the magnetic stack. Again, it should be noted that resistive semiconductor memory devices may be built having less or even more sacrificial anode layers than described in the embodiment shown in FIG. 3.

In a further embodiment of the invention, another possibility to incorporate a sacrificial anode layer into the MRAM stack is to integrate the sacrificial anode layer into the hard mask layer strucure. This particular embodiment would have the effect that the resistance of the magnetic element and thus the read signal is not changing noticeably if the sacrificial anode layer corrodes. In this embodiment, the sacrificial anode may be integrated alongside the read current path.

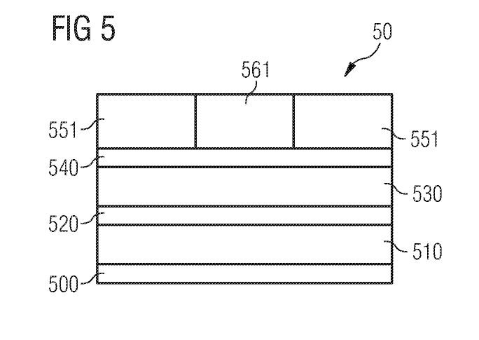

In FIG. 4 one possibility of the above-mentioned integration of the sacrificial anode layer into the hard mask layer structure is illustrated. The stack of the memory element 40 in accordance with this embodiment of the invention starts with a seed layer structure 500. On or above the seed layer structure 500, there is provided a reference magnetic layer structure 510, a tunnel barrier structure 520 and a free magnetic layer structure 530. On or above the free magnetic layer structure 530, a cap layer structure 540 may be deposited. Completing the stack, a mask layer structure 550, e.g. a hard mask 550 may be provided having a contact hole in which the sacrificial anode layer 560 may be formed, i.e. in this embodiment of the invention, the core of this layer is formed by the sacrificial anode and the outer casing is formed by the hard mask material.

A further embodiment of the invention is illustrated in FIG. 5. In this embodiment, the stack of the memory element 50 is composed in a similar way as illustrated in FIG. 4. The order of the layers starts with a seed layer structure 500, followed by a reference magnetic layer structure 510, a tunnel barrier structure 520, a free magnetic layer structure 530 and a cap layer structure 540. The upper layer may be a sacrificial anode layer 551 having a hole in the middle of the layer. A hard mask 561 may be formed within this hole, i.e. the core of this layer is formed by the hard mask material and the outer casting is formed by the sacrificial anode layer.

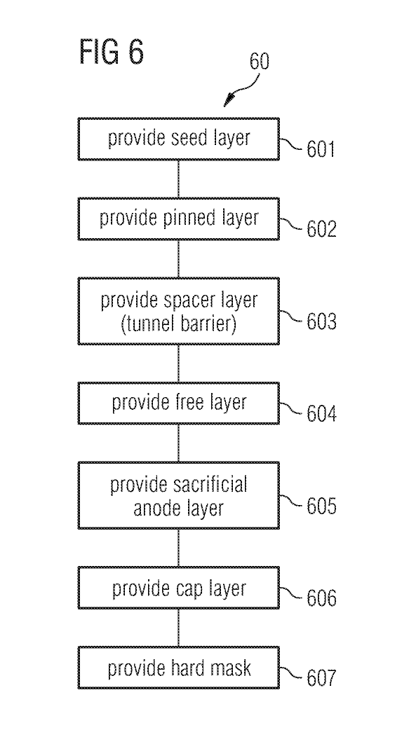

FIG. 6 is a flow diagram 60 depicting one embodiment of a method in accordance with the present invention for manufacturing a resistive semiconductor memory device in accordance with the present invention using a sacrificial anode layer. The method has already been described in the context of the resistive semiconductor memory device 20. However, the method could be used for other resistive semiconductor memory devices, such as, for example, the memory device 30. However, some steps would be in addition or in another way. Moreover, although the method is described primarily in the context of a single memory device, one of ordinary skill in the art will readily recognize that memory devices having a plurality of memory cells may be fabricated substantially simultaneously.

According to this embodiment of the invention, a resistive semiconductor memory device is manufactured by depositing a seed layer structure on a substrate (process 601). Deposition of this layer structure and the subsequent layer structures may be carried out, for example, by direct deposition, e.g. by sputtering of the material to be deposited or by direct vaporization of the material to be deposited. In the following processes, a reference magnetic layer structure or pinned layer is deposited onto the seed layer structure (process 602), a spacer layer structure is deposited onto the reference magnetic layer structure (process 603) and a free magnetic layer structure is deposited onto the spacer layer structure (process 604). Then, the sacrificial anode layer is deposited for protecting the functional magnetic layers or layer structures so that there will be substantially no electrochemical corrosion to them (process 605). Finally, a cap layer structure (process 606) and subsequently a mask layer structure (process 607) are deposited above the sacrificial anode layer to finalize the manufacture of the memory device. In an embodiment of the invention, at least one sacrificial material layer is formed to suppress electrochemical corrosion of the first magnetic layer structure or the second magnetic layer structure.

In another embodiment of the invention, the stack of the memory element may be manufactured in an alternative way. The order of the layers starts with a seed layer structure, followed by a reference magnetic layer structure, a tunnel barrier structure, a free magnetic layer structure and a cap layer structure. Then, a hard mask may be formed and patterned. After having patterned the hard mask such that the patterned hard mask structure still covers the portions of the stack of the memory element to be formed, a sacrificial anode layer may be deposited over the entire surface. Then, the sacrificial anode layer is partially removed in a spacer etch manner using an anisotropic etching process such as a sputter process or a reactive ion etching process (RIE), thereby forming spacers containing sacrificial material on the sidewalls of the remaining hard mask structure. Next, the stack of the memory element is etched using the hard mask and the remaining portions of the sacrificial anode layer as a mask.

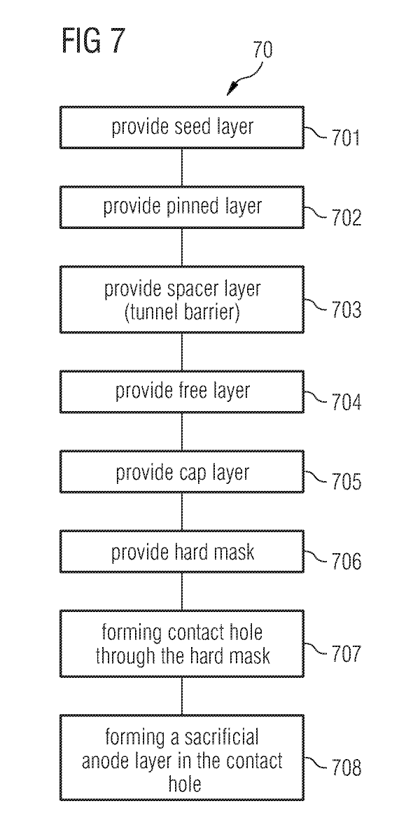

In another embodiment of the present invention a resistive semiconductor memory device is manufactured according to the a process as shown in the flow diagram 70 in FIG. 7. The process is described in the context of the resistive semiconductor memory device 40. However, the method could be used for other resistive semiconductor memory devices, such as, for example, the memory device 50.

In this particular embodiment, a seed layer structure is provided (process 701). Then, the active memory centre is deposited, i.e. a reference magnetic layer structure or pinned layer (process 702), a spacer layer structure (process 703) and a free magnetic layer structure (process 704). Subsequently, a cap layer structure may be deposited onto the free magnetic layer structure (process 705). The final layer structure of this stack is a mask layer structure, which may be provided onto the cap layer structure (process 706). In a following process, a contact hole may be formed through the mask layer structure (process 707). This may be carried out by etching the hard mask with the aid of a mask. After having formed the contact hole, a sacrificial anode layer may be formed in the contact hole (process 708). The sacrificial anode layer material can be as described above.

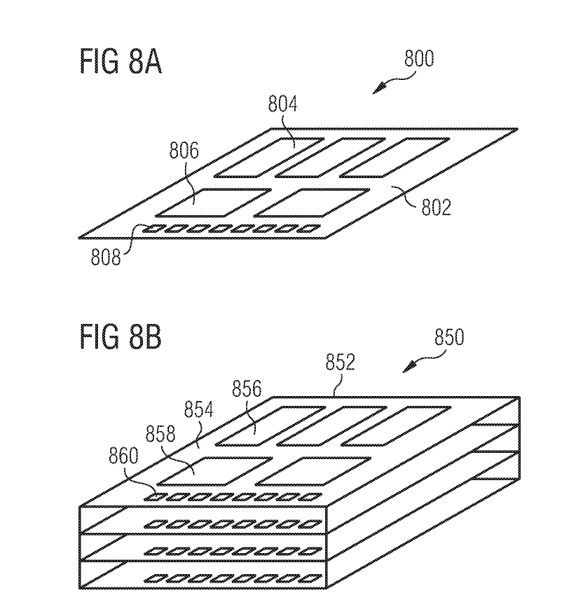

As shown in FIGS. 8A and 8B, in some embodiments, memory devices such as those described herein may be used in modules.

In FIG. 8A, a memory module 800 is shown, on which one or more memory devices 804 are arranged on a substrate 802. The memory device 804 may include numerous memory cells, each of which uses a memory element in accordance with an embodiment of the invention. The memory module 800 may also include one or more electronic devices 806, which may include memory, processing circuitry, control circuitry, addressing circuitry, bus interconnection circuitry, or other circuitry or electronic devices that may be combined on a module with a memory device, such as the memory device 804. Additionally, the memory module 800 includes multiple electrical connections 808, which may be used to connect the memory module 800 to other electronic components, including other modules.

As shown in FIG. 8B, in some embodiments, these modules may be stackable, to form a stack 850. For example, a stackable memory module 852 may contain one or more memory devices 856, arranged on a stackable substrate 854. The memory device 856 contains memory cells that employ memory elements in accordance with an embodiment of the invention. The stackable memory module 852 may also include one or more electronic devices 858, which may include memory, processing circuitry, control circuitry, addressing circuitry, bus interconnection circuitry, or other circuitry or electronic devices that may be combined on a module with a memory device, such as the memory device 856. Electrical connections 860 are used to connect the stackable memory module 852 with other modules in the stack 850, or with other electronic devices. Other modules in the stack 850 may include additional stackable memory modules, similar to the stackable memory module 852 described above, or other types of stackable modules, such as stackable processing modules, control modules, communication modules, or other modules containing electronic components.

In an embodiment of the invention, an integrated circuit having a memory cell is provided. The memory cell may include a first magnetic layer structure, a spacer layer structure disposed above the first magnetic layer structure, a second magnetic layer structure disposed above the spacer layer structure, and at least one sacrificial material layer to suppress electrochemical corrosion of the first magnetic layer structure or the second magnetic layer structure.

The spacer layer structure may be a tunnel barrier layer structure.

In an embodiment of the invention, the at least one sacrificial material layer is positioned in physical contact with the first magnetic layer structure or the second magnetic layer structure.

The integrated circuit may further include a seed layer structure, wherein the first magnetic layer structure is disposed above the seed layer structure.

The integrated circuit may further include a cap layer structure disposed above the second magnetic layer structure.

The integrated circuit may further include a mask layer structure disposed above the second magnetic layer structure.

In an embodiment of the invention, the at least one sacrificial material layer is arranged between at least two of the layer structures other than between the first magnetic layer structure and the spacer layer structure or between the spacer layer structure and the second magnetic layer structure.

In an embodiment of the invention, the at least one sacrificial material layer is arranged between each of the respective layer structures other than between the first magnetic layer structure and the spacer layer structure or between the spacer layer structure and the second magnetic layer structure.

Furthermore, in an embodiment of the invention, the at least one sacrificial material layer is made of a material being selected from a group of materials consisting of Al, Mg, Zn, Ti, Mn, CoFe alloy and CoFeB alloy or a combination or an alloy of the mentioned materials.

Further, the at least one sacrificial material layer may be arranged between two respective layers of the seed layer structure, the cap layer structure or the mask layer structure.

In an embodiment of the invention, the first magnetic layer structure is a reference magnetic layer structure, and the second magnetic layer structure is a free magnetic layer structure.

In an embodiment of the invention, the second magnetic layer structure is a reference magnetic layer structure, and the first magnetic layer structure is a free magnetic layer structure.

In an embodiment of the invention, the reference magnetic layer structure may include material being selected from a group of materials consisting of Fe, Co, Ni and combinations or alloys thereof, CoFeY, wherein Y is in the range of about five to about fifty atomic percent of at least one of B, Ta, Hf, and Zr.

Furthermore, the reference magnetic layer structure may include a plurality of magnetic layers.

In an embodiment of the invention, the reference magnetic layer structure may include a pinning structure.

The pinning structure may include material selected from a group of materials consisting of PtMn, IrMn.

The free magnetic layer structure may include material being selected from a group of materials consisting of Fe, Co, Ni and combinations or alloys thereof, CoFeY, wherein Y is in the range of about five to about fifty atomic percent of at least one of B, Ta, Hf, Zr, Pt, Tb, and Ru.

The free magnetic layer structure may include a plurality of magnetic layers.

The spacer layer structure may include material being selected from a group of materials consisting of Cu, Al, Au, Al₂O₃, MgO, Si₃N₄, NiO, HfO₂, TiO₂, NbO and SiO₂, and combinations thereof.

The cap layer structure may include material being selected from a group of materials consisting of Ta, TaN, TiN, CuN, Ru, and combinations thereof.

The mask layer structure may include material being selected from a group of materials consisting of Ti, TiN, W, WN, Ta, TaN, SiO₂, Ru and combinations thereof

The seed layer structure may include material being selected from a group of materials consisting of WN, Ta, TaN, CuN, Cu, Ru, NiFeCr and combinations thereof.

In an embodiment of the invention, an integrated circuit having a memory cell is provided. The memory cell may include a first magnetic layer structure, a spacer layer structure disposed above the first magnetic layer structure, a second magnetic layer structure disposed above the spacer layer structure, and at least one sacrificial anode layer.

The spacer layer structure may be a tunnel barrier layer structure.

In an embodiment of the invention, the integrated circuit may further include a seed layer structure, wherein the first magnetic layer structure disposed above the seed layer structure.

In an embodiment of the invention, the integrated circuit may further include a cap layer structure disposed above the second magnetic layer structure.

In an embodiment of the invention, the integrated circuit may further include a mask layer structure disposed above the second magnetic layer structure, wherein the mask layer structure comprises the at least one sacrificial anode layer.

The at least one sacrificial anode layer may be surrounded by other mask material of the mask layer structure.

The at least one sacrificial anode layer may surround other mask material of the mask layer structure.

In an embodiment of the invention, the integrated circuit may further include at least one additional sacrificial anode layer, wherein the at least one additional sacrificial anode layer is arranged between at least two of layer structures other than between the first magnetic layer structure and the spacer layer structure or between the spacer layer structure and the second magnetic layer structure.

The at least one additional sacrificial anode layer may be arranged between each of the respective layer structures other than between the first magnetic layer structure and the spacer layer structure or between the spacer layer structure and the second magnetic layer structure.

The sacrificial anode layer may include material being selected from a group of materials consisting of Al, Mg, Zn, Ti, Mn, a combination or an alloy thereof, CoFe alloy and CoFeB alloy.

The at least one sacrificial anode layer may be arranged between two respective layers of the seed layer structure, the cap layer structure or the mask layer structure.

The first magnetic layer structure may be a reference magnetic layer structure, and the second magnetic layer structure may be a free magnetic layer structure.

In an embodiment of the invention, the second magnetic layer structure is a reference magnetic layer structure, and the first magnetic layer structure is a free magnetic layer structure.

The reference magnetic layer structure may include material being selected from a group of materials consisting of Fe, Co, Ni and combinations or alloys thereof, CoFeY, wherein Y is in the range of about five to about fifty atomic percent of at least one of B, Ta, Hf, and Zr.

In an embodiment of the invention, the reference magnetic layer structure includes a plurality of magnetic layers.

The reference magnetic layer structure may include a pinning structure.

Furthermore, the pinning structure may include material selected from a group of materials consisting of PtMn, IrMn.

In an embodiment of the invention, the free magnetic layer structure includes material being selected from a group of materials consisting of Fe, Co, Ni and combinations or alloys thereof, CoFeY, wherein Y is in the range of about five to about fifty atomic percent of at least one of B, Ta, Hf, Zr, Pt, Tb, and Ru.

The free magnetic layer structure may include a plurality of magnetic layers.

The spacer layer structure may include material being selected from a group of materials consisting of Cu, Al, Au, Al₂O₃, MgO, Si₃N₄, NiO, HfO₂, TiO₂, NbO and SiO₂, and combinations thereof.

The cap layer structure may include material being selected from a group of materials consisting of Ta, TaN, TiN, CuN, Ru, and combinations thereof.

The mask layer structure may include material being selected from a group of materials consisting of Ti, TiN, W, WN, Ta, TaN, SiO₂, Ru, and combinations thereof.

The seed layer structure may include material being selected from a group of materials consisting of WN, Ta, TaN, CuN, Cu, Ru, NiFeCr and combinations thereof.

In an embodiment of the invention, a method for manufacturing an integrated circuit having a memory cell is provided. The method may include forming a first magnetic layer structure, forming a spacer layer structure disposed above the first magnetic layer structure, forming a second magnetic layer structure disposed above the spacer layer structure, and forming at least one sacrificial material layer to suppress electrochemical corrosion of the first magnetic layer structure or the second magnetic layer structure.

The spacer layer structure may be a tunnel barrier layer structure.

The at least one sacrificial material layer may be positioned in physical contact with the first magnetic layer structure or the second magnetic layer structure.

In an embodiment of the invention, the method may further include forming a seed layer structure, wherein the first magnetic layer structure is disposed above the seed layer structure.

In an embodiment of the invention, the method may further include forming a cap layer structure disposed above the second magnetic layer structure.

In an embodiment of the invention, the method may further include forming a mask layer structure disposed above the second magnetic layer structure.

In an embodiment of the invention, the at least one sacrificial material layer is arranged between at least two of the layer structures other than between the first magnetic layer structure and the spacer layer structure or between the spacer layer structure and the second magnetic layer structure.

The at least one sacrificial material layer may be arranged between each of the respective layer structures other than between the first magnetic layer structure and the spacer layer structure or between the spacer layer structure and the second magnetic layer structure.

The at least one sacrificial material layer may be made of a material being selected from a group of materials consisting of Al, Mg, Zn, Ti, Mn, CoFe alloy and CoFeB alloy or a combination or an alloy of the mentioned materials.

The at least one sacrificial material layer may be arranged between two respective layers of the seed layer structure, the cap layer structure or the mask layer structure.

In an embodiment of the invention, the first magnetic layer structure is a reference magnetic layer structure, and the second magnetic layer structure is a free magnetic layer structure.

In an embodiment of the invention, the second magnetic layer structure is a reference magnetic layer structure, and the first magnetic layer structure is a free magnetic layer structure.

The reference magnetic layer structure may include material being selected from a group of materials consisting of Fe, Co, Ni and combinations or alloys thereof, CoFeY, wherein Y is in the range of about five to about fifty atomic percent of at least one of B, Ta, Hf, and Zr.

The reference magnetic layer structure may include a plurality of magnetic layers.

The reference magnetic layer structure may include a pinning structure.

The pinning structure may include material selected from a group of materials consisting of PtMn, IrMn.

The free magnetic layer structure may include material being selected from a group of materials consisting of Fe, Co, Ni and combinations or alloys thereof, CoFeY, wherein Y is in the range of about five to about fifty atomic percent of at least one of B, Ta, Hf, Zr, Pt, Tb, and Ru.

The free magnetic layer structure may include a plurality of magnetic layers.

The spacer layer structure may include material being selected from a group of materials consisting of Cu, Al, Au, Al₂O₃, MgO, Si₃N₄, NiO, HfO₂, TiO₂, NbO and SiO₂, and combinations thereof.

The cap layer structure may include material being selected from a group of materials consisting of Ta, TaN, TiN, CuN, Ru, and combinations thereof.

The mask layer structure may include material being selected from a group of materials consisting of Ti, TiN, W, WN, Ta, TaN, SiO₂, Ru and combinations thereof

The seed layer structure may include material being selected from a group of materials consisting of WN, Ta, TaN, CuN, Cu, Ru, NiFeCr and combinations thereof.

In another embodiment of the invention, a method for manufacturing an integrated circuit having a memory cell is provided. The method may include forming a first magnetic layer structure, forming a spacer layer structure disposed above the first magnetic layer structure, forming a second magnetic layer structure disposed above the spacer layer structure, and forming at least one sacrificial anode layer.

The spacer layer structure may be a tunnel barrier layer structure.

In an embodiment of the invention, the method may further include forming a seed layer structure, wherein the first magnetic layer structure is disposed above the seed layer structure.

In an embodiment of the invention, the method may further include forming a cap layer structure disposed above the second magnetic layer structure.

In an embodiment of the invention, the method may further include forming a mask layer structure disposed above the second magnetic layer structure, wherein the mask layer structure comprises the at least one sacrificial anode layer.

The at least one sacrificial anode layer may be formed such that it is surrounded by other mask material of the mask layer structure.

The at least one sacrificial anode layer may be formed such that it surrounds other mask material of the mask layer structure.

In an embodiment of the invention, the method may further include forming at least one additional sacrificial anode layer, wherein the at least one additional sacrificial anode layer is arranged between at least two of layer structures other than between the first magnetic layer structure and the spacer layer structure or between the spacer layer structure and the second magnetic layer structure.

In an embodiment of the invention, the at least one additional sacrificial anode layer is arranged between each of the respective layer structures other than between the first magnetic layer structure and the spacer layer structure or between the spacer layer structure and the second magnetic layer structure.

The sacrificial anode layer may include material being selected from a group of materials consisting of Al, Mg, Zn, Ti, Mn, a combination or an alloy thereof, CoFe alloy and CoFeB alloy.

The at least one sacrificial anode layer may be arranged between two respective layers of the seed layer structure, the cap layer structure or the mask layer structure.

In an embodiment of the invention, the first magnetic layer structure is a reference magnetic layer structure, and the second magnetic layer structure is a free magnetic layer structure.

In an embodiment of the invention, the second magnetic layer structure is a reference magnetic layer structure, and the first magnetic layer structure is a free magnetic layer structure.

The reference magnetic layer structure may include material being selected from a group of materials consisting of Fe, Co, Ni and combinations or alloys thereof, CoFeY, wherein Y is in the range of about five to about fifty atomic percent of at least one of B, Ta, Hf, and Zr.

The reference magnetic layer structure may include a plurality of magnetic layers.

In an embodiment of the invention, the reference magnetic layer structure may include a pinning structure.

The pinning structure may include material selected from a group of materials consisting of PtMn, IrMn.

The free magnetic layer structure may include material being selected from a group of materials consisting of Fe, Co, Ni and combinations or alloys thereof, CoFeY, wherein Y is in the range of about five to about fifty atomic percent of at least one of B, Ta, Hf, Zr, Pt, Tb, Ru.

The free magnetic layer structure may include a plurality of magnetic layers.

The spacer layer structure may include material being selected from a group of materials consisting of Cu, Al, Au, Al₂O₃, MgO, Si₃N₄, NiO, HfO₂, TiO₂, NbO and SiO₂, and combinations thereof.

The cap layer structure may include material being selected from a group of materials consisting of Ta, TaN, TiN, CuN, Ru, and combinations thereof.

The mask layer structure may include material being selected from a group of materials consisting of Ti, TiN, W, WN, Ta, TaN, SiO₂ and combinations thereof.

The seed layer structure may include material being selected from a group of materials consisting of WN, Ta, TaN, CuN, Cu, Ru, NiFeCr and combinations thereof.

In an embodiment of the invention, an integrated circuit having a memory cell is provided. The memory cell may include a seed layer structure, a first magnetic layer structure disposed above the seed layer structure, a tunnel barrier layer structure disposed above the first magnetic layer structure, a second magnetic layer structure disposed above the tunnel barrier layer structure, a cap layer structure disposed above the second magnetic layer structure, a mask layer structure disposed above the cap layer structure, and at least one sacrificial material means for suppressing electrochemical corrosion of the first magnetic layer structure or the second magnetic layer structure.

In an embodiment of the invention, an integrated circuit having a memory cell is provided. The memory cell may include a first magnetic layer structure, a tunnel barrier layer structure disposed above the first magnetic layer structure, a second magnetic layer structure disposed above the tunnel barrier layer structure, and at least one sacrificial anode layer means.

In yet another embodiment of the invention, a memory module is provided. The memory module may include a plurality of integrated circuits, wherein at least one integrated circuit of the plurality of integrated circuits includes a memory cell. The memory cell may include a first magnetic layer structure, a tunnel barrier layer structure disposed above the first magnetic layer structure, a second magnetic layer structure disposed above the tunnel barrier layer structure, and at least one sacrificial material layer to suppress electrochemical corrosion of the first magnetic layer structure or the second magnetic layer structure.

The memory module may be a stackable memory module in which at least some of the integrated circuits are stacked one above the other.

In yet another embodiment of the invention, a memory module is provided. The memory module may include a plurality of integrated circuits, wherein at least one integrated circuit of the plurality of integrated circuits includes a memory cell. The memory cell may include a first magnetic layer structure, a tunnel barrier layer structure disposed above the first magnetic layer structure, a second magnetic layer structure disposed above the tunnel barrier layer structure, and at least one sacrificial anode layer.

The memory module may be a stackable memory module in which at least some of the integrated circuits are stacked one above the other.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. An integrated circuit having a memory cell, the memory cell comprising:
a first magnetic layer structure;
a spacer layer structure disposed above the first magnetic layer structure;
a second magnetic layer structure disposed above the spacer layer structure; and
at least one sacrificial material layer to suppress electrochemical corrosion of the first magnetic layer structure or the second magnetic layer structure.

2. The integrated circuit of claim 1, wherein the spacer layer structure is a tunnel barrier layer structure.

3. The integrated circuit of claim 1, wherein the at least one sacrificial material layer is positioned in physical contact with the first magnetic layer structure or the second magnetic layer structure.

4. The integrated circuit of claim 1, further comprising a seed layer structure, wherein the first magnetic layer structure is disposed above the seed layer structure.

5. The integrated circuit of claim 1, further comprising a cap layer structure disposed above the second magnetic layer structure.

6. The integrated circuit of claim 1, wherein the at least one sacrificial material layer is arranged between at least two of the layer structures other than between the first magnetic layer structure and the spacer layer structure or between the spacer layer structure and the second magnetic layer structure.

7. The integrated circuit of claim 1, wherein the at least one sacrificial material layer comprises a material selected from the group of materials consisting of Al, Mg, Zn, Ti, Mn, CoFe alloy and CoFeB alloy and combinations and alloys of the mentioned materials.

8. The integrated circuit of claim 1, wherein the first magnetic layer structure is a reference magnetic layer structure and the second magnetic layer structure is a free magnetic layer structure.

9. The integrated circuit of claim 1, wherein the second magnetic layer structure is a reference magnetic layer structure and the first magnetic layer structure is a free magnetic layer structure.

10. An integrated circuit having a memory cell, the memory cell comprising:
a first magnetic layer structure;
a spacer layer structure disposed above the first magnetic layer structure;
a second magnetic layer structure disposed above the spacer layer structure; and
at least one sacrificial anode layer adjacent the first magnetic layer structure or the second magnetic layer structure.

11. The integrated circuit of claim 10, wherein the spacer layer structure is a tunnel barrier layer structure.

12. The integrated circuit of claim 10, further comprising a seed layer structure, wherein the first magnetic layer structure is disposed above the seed layer structure.

13. The integrated circuit of claim 10, further comprising a cap layer structure disposed above the second magnetic layer structure.

14. The integrated circuit of claim 10, further comprising at least one additional sacrificial anode layer, wherein the at least one additional sacrificial anode layer is arranged between at least two layer structures other than between the first magnetic layer structure and the spacer layer structure or between the spacer layer structure and the second magnetic layer structure.

15. The integrated circuit of claim 10, wherein the first magnetic layer structure is a reference magnetic layer structure and the second magnetic layer structure is a free magnetic layer structure.

16. The integrated circuit of claim 10, wherein the second magnetic layer structure is a reference magnetic layer structure and the first magnetic layer structure is a free magnetic layer structure.

17. A method for manufacturing an integrated circuit, the method comprising:
forming a first magnetic layer structure;
forming a spacer layer structure over the first magnetic layer structure;
forming a second magnetic layer structure over the spacer layer structure; and
forming at least one sacrificial material layer to suppress electrochemical corrosion of the first magnetic layer structure or the second magnetic layer structure.

18. The method of claim 17, wherein the spacer layer structure is a tunnel barrier layer structure.

19. The method of claim 17, wherein the at least one sacrificial material layer is formed in physical contact with the first magnetic layer structure or the second magnetic layer structure.

20. The method of claim 17, further comprising forming a seed layer structure, wherein the first magnetic layer structure is disposed above the seed layer structure.

21. A method for manufacturing an integrated circuit, the method comprising:
forming a first magnetic layer structure;
forming a spacer layer structure over the first magnetic layer structure;
forming a second magnetic layer structure over the spacer layer structure; and
forming at least one sacrificial anode layer adjacent the first magnetic layer structure or the second magnetic layer structure.

22. The method of claim 21, wherein the spacer layer structure is a tunnel barrier layer structure.

23. The method of claim 21, further comprising forming a seed layer structure, wherein the first magnetic layer structure is formed over the seed layer structure.

24. The method of claim 21, further comprising forming a cap layer structure disposed above the second magnetic layer structure.

25. An integrated circuit having a memory cell, the memory cell comprising:
a seed layer structure;
a first magnetic layer structure disposed above the seed layer structure;
a tunnel barrier layer structure disposed above the first magnetic layer structure;
a second magnetic layer structure disposed above the tunnel barrier layer structure;
a cap layer structure disposed above the second magnetic layer structure;
a mask layer structure disposed above the cap layer structure; and
at least one sacrificial material means for suppressing electrochemical corrosion of the first magnetic layer structure or the second magnetic layer structure.
